(19) United States
(12) Patent Application Publication
(10) Pub. No.: US 2026/0353598 A1
(43) Pub. Date: Nov. 5, 2026

(54) ELECTRONIC DEVICES HAVING INLETS FOR AIRFLOW MANAGEMENT AND RELATED SYSTEMS AND METHODS

(71) Applicant: Intel Products IP LLC, Santa Clara, CA (US)

(72) Inventors: Hamid Mohammadmirzaiedaryan, Toronto (CA); Ali Kalantarian, Richmond Hill (CA); Jacob Michael Title, Thornhill (CA)

(73) Assignee: Intel Products IP LLC, Santa Clara, CA (US)

(21) Appl. No.: 19/718,627

(22) Filed: Jun. 24, 2026

(51) Int. Cl. H05K 7/20

(52) U.S. Cl. CPC H05K 7/20172; H05K 7/20154

(57) ABSTRACT

Example electronic devices having inlets for airflow management and related systems and methods are disclosed. An example apparatus includes a housing; a blower having a blower inlet, the blower in the housing; and an inlet defined by a surface of the housing, the inlet having a first inlet portion defined by a first portion of the surface and a second inlet portion defined by a second portion of the surface, the second portion of the surface extending over a portion of the blower inlet.

### BACKGROUND

An electronic device such as a graphics card includes one or more inlets to receive air into a housing of the electronic device and a blower to circulate the air through the housing to cool the electronic device.

### BRIEF DESCRIPTION OF THE DRAWINGS

FIG. 1 illustrates an example electronic device including a housing defining an inlet in accordance with teachings of this disclosure.

FIG. 2 is a cutaway view of the example electronic device of FIG. 1.

FIG. 3 is a schematic of an example recirculation flow path defined in the housing of the example electronic device of FIGS. 1 and 2 in accordance with teachings of this disclosure.

FIG. 4 is a flowchart of an example method of manufacturing an electronic device including a recirculation flow path in accordance with teachings of this disclosure.

In general, the same reference numbers will be used throughout the drawing(s) and accompanying written description to refer to the same or like parts. The figures are not necessarily to scale.

### DETAILED DESCRIPTION

An electronic device such as graphics card outputs heat during performance of workloads. The electronic device includes one or more inlets to receive air into a housing of the electronic device and a blower or a fan to circulate the air through the housing to cool the component of the electronic device. Removal of heat from, for instance, a graphics processing unit (GPU) of the graphics card, facilitates temperature control of the GPU and performance stability.

As workloads performed by the electronic device increase, the amount of heat generated by the components of the electronic device increases and, thus, the amount of heat to be dissipated also increases. However, increasing rotational speed of the blower or the fan to facilitate circulation of cool air also increases noise outputs. Increased noise can contribute to a negative user experience and/or fail to meet industry acoustic standards. Thus, efforts to manage thermal performance should be balanced in view of acoustic constraints.

The blower of the electronic device functions as a centrifugal fan that generates pressure to drive airflow through the housing. For example, during operation of the blower, air is drawn in axially through an inlet defined in the housing of the electronic device that is aligned or substantially aligned with an inlet of the blower. The air is accelerated radially outward via the blower toward components in the electronic device, such as a heat sink. Most of the air exiting the blower passes through the heat sink and other parts of the housing and ultimately exits via vents defined in the housing, thereby removing heat from the housing. However, back pressure may form near components proximate to the blower, such as the heat sink. The rotation of the blower contributes to the formation of reverse airflow between, for example, the blower and the heat sink. The rotation of the blower can drive the reverse airflow to exit the electronic device via the same inlet that the air entered the device housing. In some instances, interactions between the intake airflow and the reverse airflow at the edges of the blower and/or the housing inlet can result in the formation of vortical structures. Vortical structures can contribute to acoustic noise.

Some known techniques for reducing acoustic noise outputs while providing for increased cooling in the housing include adding a vapor chamber to the housing, which reduces available real estate for electronic components and increased costs. Other options include using low-profile (e.g., lower height) electronic components on a printed circuit board in the housing. In some examples, taller electronic components (e.g., input and/or output capacitors) can result in formation of cutouts in the heats sink fins and/or a ramped portion of the heat sink proximate to the blower to cover the taller electronic components with the heat sink. However, the ramped portion and/or cutouts in the heat sink can affect airflow through the heat sink and heat sink efficiency. Although lower profile electronic components may provide less airflow disruption in the device housing, such electronic components may be more expensive and increase bill of materials costs for manufacturing the electronic device.

Disclosed herein are example inlets for electronic devices to increase airflow through the electronic device without increasing acoustic noise output. Example inlets disclosed herein reduce reverse airflow that would otherwise exit the housing of the electronic device via a same inlet in the housing that receives intake air for a blower or a fan. The disclosed housing inlets redirect the reverse flow to an inlet of the blower or the fan, thereby increasing airflow received at the housing. For example, a shape of the housing inlet results in formation of a flow path that directs (e.g., returns) the reverse flow to the inlet of the blower. By redirecting the reverse airflow that would otherwise exit the device back to the blower, examples disclosed herein facilitate increased cooling of the components of the electronic device and, thus, support increased total board power (e.g., power draw or consumption by a GPU). Further, by reducing the amount of reverse flow that exits the device housing, examples disclosed herein eliminate or substantially reduce the formation of vortices at the housing inlet, thereby reducing or otherwise not increasing the acoustic noise output. As a result, example housing inlets disclosed herein increase net intake airflow to cool the electronic device without compromising acoustic performance.

Although examples disclosed herein are primarily discussed in connection with graphics cards, the disclosed examples can be used with other types of electronic devices such as central processing units (CPUs), solid state drives (SSDs), hard disk drives (HDDs), and memory cards.

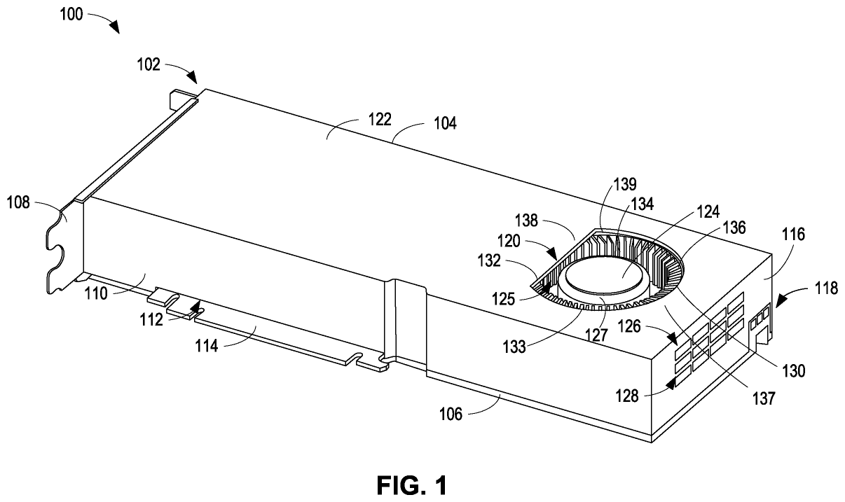

FIG. 1 illustrates an example electronic device 100. In the example of FIG. 1, the electronic device 100 is a graphics card. Electronic components (e.g., a GPU, memory components) of the electronic device 100 are in a housing 102. The housing 102 of the electronic device 100 is formed by a cover or shroud 104 and a backplate 106 that is coupled to the shroud 104. The shroud 104 can be made of, for example, a plastic material.

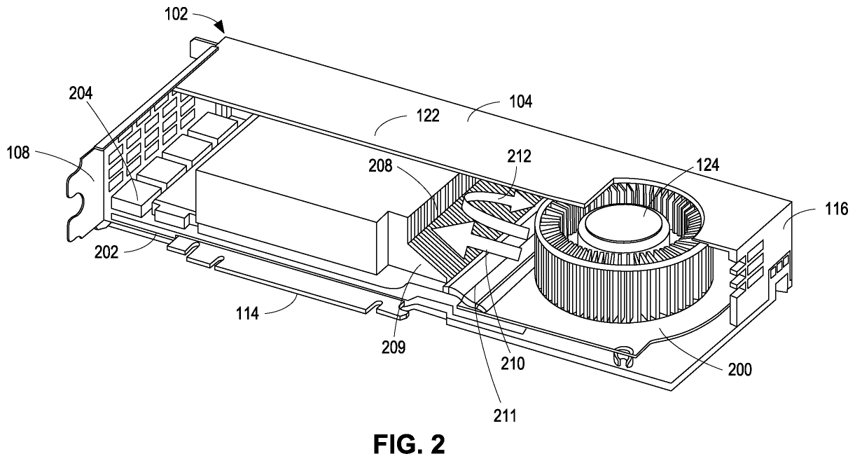

The housing 102 support components to facilitate connections or interfaces between the electronic device 100 and, for example, other electronic devices in a chassis. For example, an input/output (I/O) bracket 108 is coupled to the shroud 104 and defines at least a portion of an end of the housing 102. A first surface 110 of the shroud 104 can define a slot 112 to receive a Peripheral Component Interconnect Express (PCIe) connector 114 (which, in this example, extends from a printed circuit board (FIG. 2)). Also, a second surface 116 of the shroud 104 defines one or more openings 118 to receive power connectors, cables, etc.

The shroud 104 includes an aperture or opening 120 defined in a third surface 122 of the shroud 104. The aperture 120 serves as an inlet for a blower 124 in the housing 102 and will here forth be referred to as a housing inlet 120. As shown in FIG. 2, the blower 124 is positioned in the housing 102 such that an inlet 125 of the blower 124 is aligned (e.g., axially aligned) or substantially aligned with the housing inlet 120 (e.g., the housing inlet 120 is an opening to the blower inlet 125). The blower 124 includes a shaft 127 that couples to a motor that drives the blower 124. Air passing through the housing inlet 120 is received in the blower inlet 125 and circulated via vanes 134 of an impeller 136 of the blower 124, thereby generating pressure to direct the air through the housing 102. The air exits the blower 124 and travels toward, for example, a heat sink in the housing 102 to facilitate cooling of the electronic components of the electronic device 100. Although the example housing 102 of FIG. 1 carries the blower 124, in other examples, a fan can be carried by the housing 102 to cool the electronic components of the graphics card. A location of the housing inlet 120 and, thus, the blower 124, relative to the shroud 104 can differ from the example of FIG. 1.

The example shroud 104 of FIG. 1 includes a vent 126 defined by openings 128 in the second surface 116 of the shroud 104. The vent 126 provides for supplemental air to the blower 124 in addition to the air entering via the housing inlet 120. A location, a size, and/or a shape of the vent 126 can differ from the example shown in FIG. 1.

In the example of FIG. 1, a shape of the housing inlet 120 is defined in the third surface 122 of the shroud 104. The housing inlet 120 includes a first inlet portion 130 and a second inlet portion 132. The first inlet portion 130 and the second inlet portion 132 form an edge 133 of the housing inlet 120. In the example of FIG. 1, the first inlet portion 130 has a different shape than the second inlet portion 132. As shown in FIG. 1, the first inlet portion 130 is curved and the second inlet portion 132 is straight (e.g., the edge 133 associated with the second inlet portion 132 forms a straight line) or substantially straight. Thus, in the example of FIG. 1, the shape of the housing inlet 120 resembles the capital letter “D.” Therefore, in the example of FIG. 1, the housing inlet 120 has a partially rounded (e.g., semi-circular) shape as compared to an inlet that is a complete circle. More generally, the housing inlet 120 has a non-circular shape.

In the example of FIG. 1, the vanes 134 of the blower 124 are arranged in a circular or substantially circular shape about a rim 139 of the impeller 136. A portion 137 of the third surface 122 of the shroud 104 defines the first inlet portion 130 such that the edge 133 of the housing inlet 120 that includes the first inlet portion 130 extends or substantially extends along the rim 139 of the impeller 136. As shown in FIG. 1, a portion 138 of the third surface 122 of the shroud 104 that defines the second inlet portion 132 extends past the rim 139 of the impeller 136 and, thus, covers an entirety of some (e.g., a first set) of the vanes 134. Further, as shown in FIG. 1, the shroud portion 138 defining the second inlet portion 132 extends into a portion of the blower inlet 125. Thus, the shroud portion 138 that defines the second inlet portion 132 extends toward a center of the blower 124 such that at least a portion of the edge 133 defined by the second inlet portion 132 is closer to the center of the blower 124 than the portion of the edge 133 defined by the first inlet portion 130. Put another way, the shroud portion 138 that defines the second inlet portion 132 extends closer to the shaft 127 than the shroud portion 137 that defines the first inlet portion 130.

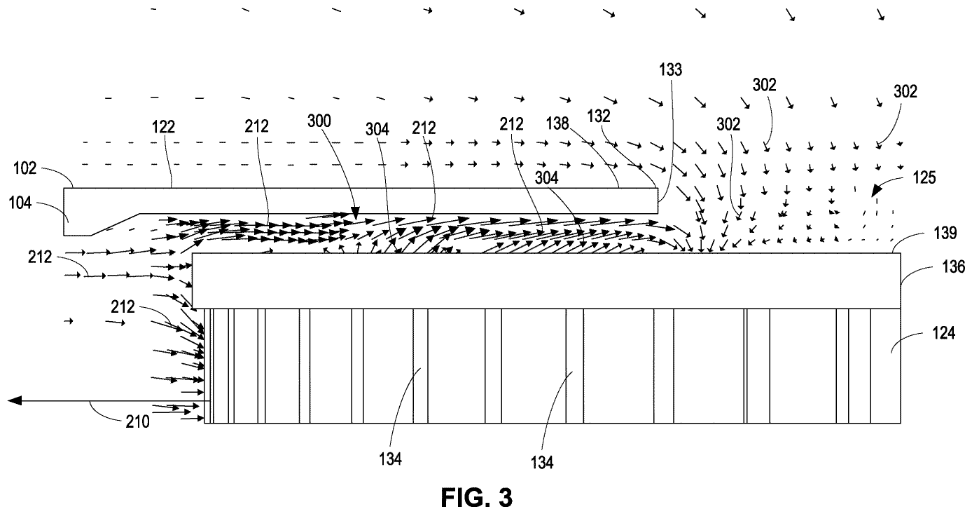

Thus, in the example of FIG. 1, rather than a circle having a circumference that aligns or substantially aligns with the circumference of the impeller 136 of the blower 124, the third surface 122 of the shroud 104 defines a modified inlet shape having a semi-circular first inlet portion 130 and a straight or substantially straight second inlet portion 132. As disclosed herein (FIG. 3), the portion 138 of the third surface 122 of the shroud 104 defining the second inlet portion 132 forms a flow path for reverse airflow in the housing 102, or airflow that moves toward the blower inlet 125. The flow path formed by the shroud portion 138 of the third surface 122 redirects the reverse airflow that would otherwise exit the housing inlet 120 back to the inlet 125 of the blower 124.

Thus, in the example of FIG. 1, the shape of the housing inlet 120 is defined by (a) a first inlet portion 130 having a shape that is substantially based on a shape of the blower 124 (e.g., a shape that aligns or substantially aligns with a circumference of the blower 124) and (b) a second inlet portion 132 that is associated with a flow path for directing reverse airflow to the blower inlet 125. The shape of the housing inlet 120 can differ from the example shown in FIG. 1. For example, a length of the second inlet portion 132 can be longer or shorter than shown in FIG. 1. In some examples, the second inlet portion 132 is at least partially curved. In some such examples, a degree of curvature of the second inlet portion 132 may be less than a degree of curvature of the first inlet portion 130.

FIG. 2 is a cutaway view of the example housing 102 of the electronic device 100 of FIG. 1, in which the first surface 110 has been removed and portions of the second surface 116 and the third surface 122 have been removed to illustrate components in the interior of the housing 102. As shown in FIG. 2, a blower mount 200 (e.g., a platform or other surface) supports the blower 124 in the housing 102. In addition to the blower 124, the housing 102 carries a printed circuit board (PCB) 202 to support electronic components 204 such as a GPU, memory devices, display ports, etc. (where the PCB 202 and electronic components 204 coupled thereto form the graphics card). A heat sink 208 is located above the printed circuit board 202 to absorb heat output by the electronic components of the printed circuit board 202. In the example of FIG. 2, the heat sink 208 is adjacent to the blower 124. The blower 124 directs air in the direction of the heat sink 208 to facilitate removal of the heat, as represented by arrow 210 in FIG. 2.

The blower 124 serves as a centrifugal fan to generate pressure to direct the air in the direction of the heat sink 208. The air flows through the heat sink 208 toward the I/O bracket 108 as represented by arrow 210 in FIG. 2. However, factors such as the size of the heat sink 208, a geometry of the heat sink 208, and/or the density of the fins of the heat sink 208 can affect the flow of the air through the heat sink 208 by blocking the airflow path or otherwise increasing flow resistance. For example, an increased number of fins of the heat sink 208 can increase resistance to airflow through the fins. As another example, the heat sink 208 includes a ramped portion 209, which can affect the trajectory of the airflow through the heat sink 208. The ramped portion 209 can be formed to cover electronic components 204 (e.g., input and/or output capacitors) coupled to the PCB 202. In some examples, the heat sink 208 includes one or more cutouts (not shown) in the ramped portion 209 or at other locations to accommodate a height of electronic component(s) 204 extending from the PCB 202. In some examples, other ramp structure(s) 211 may be formed proximate to the blower 124 to cover electronic components in an effort to reduce disruption of the airflow toward the heat sink 208. However, the ramped portion 209 of the heat sink 208 and/or the ramp structure(s) 211 can affect the flow of air exiting the blower 124. In particular, the rotation of the blower 124 and the geometry of the heat sink 208, fin density, and/or the ramp structure(s) 211 can contribute to the formation of back pressure in the housing 102. The back pressure pushes at least some of the air flowing in the direction of arrow 210 in the reverse direction, thereby forming reverse airflow in the housing 102, or airflow in the direction toward the blower 124, as represented by arrow 212 in FIG. 2

Other electronic components 204 (e.g., display ports) in the housing 102 and/or coupled to the housing 102 (e.g., the I/O bracket 108) can affect (e.g., increase) flow resistance by blocking airflow path(s). Thus, the presence and/or geometry of components in the housing 102 can impact (e.g., increase) resistance to airflow through the housing. The effects of the housing components on the airflow path(s) along with rotation of the blower 124 contribute to the generation of back pressure in the housing 102. The back pressure causes reverse airflow in the housing 102, or airflow in the direction toward the blower 124, as represented by arrow 212 in FIG. 2.

FIG. 3 is a schematic of a recirculation flow path 300 defined by the portion 138 of the third surface 122 of the shroud 104 that defines the second inlet portion 132 of the example housing inlet 120 of FIG. 1. Air enters the inlet 125 of the blower 124 as intake flow, as represented by arrows 302 in FIG. 3. As discussed in connection with FIG. 2, the blower 124 generates pressure to drive the air in the direction of the heat sink 208 (FIG. 2), as represented by arrow 210 in FIG. 3. As also discussed in connection with FIG. 2, reverse flow is generated due to creation of back pressure in the housing 102 (e.g., due to airflow resistance). The reverse flow is represented by arrows 212 in FIG. 3.

The rotation of the blower 124 drives the reverse flow in the housing 102 toward the blower 124. For example, the reverse flow moves in a direction extending from the heat sink 208 toward the blower 124. As shown in FIG. 3, the shroud portion 138 extends over a portion of the blower 124 and covers some of the vanes 134 that are proximate to the second inlet portion 132 of the housing inlet edge 133. Also, in this example, the shroud portion 138 extends over the rim 139 of the impeller 136 into a portion of the blower inlet 125. As shown in FIG. 3, the recirculation flow path 300 is defined between the blower 124 and the portion of the shroud portion 138 that extends over the blower 124. For example, the recirculation flow path 300 extends along a space between the shroud portion 138 and the impeller rim 139 and into the blower inlet 125. Thus, the shroud portion 138 serves as an extension that forms the airflow path 300 within the housing 102 to the blower inlet 125. The recirculation flow path 300 directs the reverse airflow 212 to travel between the shroud portion 138 and the blower 124 past the impeller rim 139 toward the blower inlet 125. The shroud portion 138 covers some of the blower inlet 125 and, thus, guides the air within the housing 102, thereby preventing the air from exiting the housing 102. Instead, the air exiting the recirculation flow path rejoins the intake air 302. As a result, the reverse airflow (or a substantial portion thereof) re-enters the blower inlet 125 and is re-distributed in a radially outward direction via the vanes 134. For example, the reverse airflow 212 travels along the recirculation flow path 300 and joins the intake flow 302 upon reaching the second inlet portion 132 of the inlet edge 133 due to vacuum pressures created by the blower 124. If the recirculation flow path 300 was not present (e.g., if the shroud portion 138 did not extend beyond the rim 139 of the impeller 136), the reverse airflow 212 would be more likely to exit via the housing inlet 120 rather than rejoining the intake flow 300. Thus, rather than exiting the housing inlet 120 in the opposite direction of the intake flow 300, which could result in formation of vortices and associated acoustic noise, the recirculation flow path 300 shown in FIG. 3 directs or guides the reverse airflow 212 such that a substantial portion of the reverse airflow 212 re-enters the blower 124 via the blower inlet 125. In some examples, the reverse airflow 212 includes air that exits the vanes 134 and directly or substantially directly enters the recirculation flow path 300, as presented by arrows 304 in FIG. 3.

Because the reverse airflow 212 has not traveled through a substantial portion of the housing 102, the reverse airflow 212 has not absorbed a substantial amount of heat and, thus, can be considered cool air available for cooling upon reentry into the housing 102 via the recirculation flow path 300. Therefore, the re-direction of the reverse airflow 212 into the blower inlet 125 increases the net intake of cool (or cooler) air entering the housing 102. For example, as a result of the disclosed housing inlet 120 and associated recirculation flow path 300, a 7.3% increase in net intake airflow can be achieved as compared to a completely circular inlet design that does not include the recirculation flow path 300 (e.g., a design in which the second inlet portion 132 of the inlet edge 133 does not extend past the rim 139 of the impeller 136). A 7.3% increase in net air intake using a known completely circular inlet design that does not include the recirculation flow path 300 can result in 2.3 dBA increase in acoustic noise output. Therefore, the disclosed housing inlet 120 and associated recirculation flow path 300 provides for increased air intake (e.g., 7.3% more intake) and with less sound pressure (e.g., 2.3 dBA less sound pressure less, which can correspond to 31% less sound pressure as compared to completely circular inlet shapes without the recirculation flow path 300).

As a result of achieving increased net intake air with improved thermo-acoustic performance, the housing 102 of the electronic device of FIG. 1-3 can include electronic components 204 having taller profiles that result in the inclusion of the ramped portion 209 of the heat sink 208 and/or other ramp structure(s) 211 in the housing 102. Thus, rather than reselecting the electronic components 204 to include, for example, low profile components, examples disclosed herein accommodate components in the housing 102 that may affect airflow paths by facilitating air intake and reducing reverse airflow via the recirculation flow path 300.

The size and/or the shape of the recirculation flow path 300 can differ from the example shown in FIG. 3. Additionally or alternatively, other portions of the housing inlet 120 can be formed to include recirculation flow path(s) 300 by extending the third surface 122 of the shroud 104 over the blower vanes 134 (e.g., past the rim 139 of the impeller 136). The length of the recirculation flow path(s) 300 can be selected to balance the amount of air that can enter the blower 124 with reduction in the amount of reverse airflow that exits via the housing inlet 120. For example, the length of the recirculation flow path(s) 300 can be selected to be long enough to guide the reverse airflow 212 to re-enter the blower inlet 125 but not so long as to block the intake air such that the net amount of intake air would be reduced or substantially reduced.

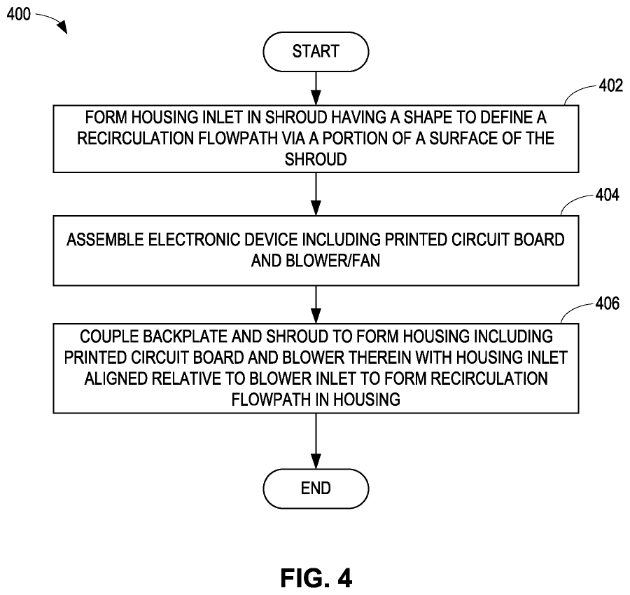

FIG. 4 is a flowchart of an example method 400 for manufacturing an electronic device (e.g., the electronic device 100) having a recirculation flow path for reverse airflow. At block 402, the example method includes forming a housing inlet 120 in a shroud 104 having a shape that is to define a recirculation flow path 300 via a portion 138 of a surface 122 of the shroud 104. For example, the housing inlet 120 can have a first inlet portion 130 and a second inlet portion 132, where the portion 138 of the shroud 104 defining the second inlet portion 132 extends further over the rim 139 of the impeller 136 than a portion of the shroud 104 forming the first inlet portion 130 to define the recirculation flow path 300 For example, the first inlet portion 130 can be circular and the second inlet portion 132 can be substantially straight such that the inlet edge 133 has a “D” shape. At block 404, the example method 400 includes assembling the electronic device 100 including, for example, the printed circuit board 202 including electronic components 204 and blower 124 (or a fan). At block 406, the example method includes coupling a backplate 106 and the shroud 104 to form a housing 102 of the electronic device 100 such that the housing inlet 120 is aligned relative to an inlet 125 of the blower 124 to form the recirculation flow path 300 in the housing 102.

While an example manner of providing an electronic device having a recirculation flow path is illustrated in FIG. 4, one or more of the elements, processes and/or devices illustrated in FIG. 4 may be combined, divided, re-arranged, omitted, eliminated, and/or implemented in any other way.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

From the foregoing, it will be appreciated that example systems, apparatus, articles of manufacture, and methods have been disclosed that provide for an inlet for a blower or fan of an electronic device formed in a surface of the device housing, where a shape of the inlet results in formation of a recirculation flow path in the housing. The recirculation flow path directs reverse airflow formed due to back pressure in the housing to the inlet of the blower for redistribution in the housing. Example inlets disclosed herein facilitate increased net intake of airflow without elevating noise output, thereby increasing thermo-acoustic performance of the electronic device.

Example electronic devices having inlets for airflow management and related systems and methods are disclosed. Further examples and combinations thereof include the following:

Example 1 includes an apparatus including a housing; a blower in the housing, the blower having a blower inlet; and an inlet defined by a surface of the housing, the inlet having a first inlet portion defined by a first portion of the surface and a second inlet portion defined by a second portion of the surface, the second portion of the surface extending over a portion of the blower inlet.

Example 2 includes any preceding clause(s) of Example 1, wherein the first inlet portion defines a first shape and the second inlet portion defines a second shape different than the first shape.

Example 3 includes any preceding clause(s) of any one or more of Examples 1 and 2, wherein the first inlet portion has a semi-circular shape.

Example 4 includes any preceding clause(s) of any one or more of Examples 1-3, wherein the second inlet portion is straight.

Example 5 includes any preceding clause(s) of any one or more of Examples 1-4, wherein the blower includes an impeller and the first portion of the surface extends along a rim of the impeller and the second portion of the surface extends past the rim of the impeller.

Example 6 includes any preceding clause(s) of any one or more of Examples 1-5, wherein a flow path in the housing is defined between the second portion of the surface and the rim of the impeller, the flow path extending to an edge of the inlet defined by the first inlet portion.

Example 7 includes any preceding clause(s) of any one or more of Examples 1-6, wherein the surface is a first surface of the housing and further includes a vent defined in a second surface of the housing.

Example 8 includes an apparatus including a blower having a blower inlet and an impeller, the impeller having a rim; and a housing carrying the blower, the housing having a housing inlet defined in a surface of the housing, the housing inlet opening to the blower inlet, the housing inlet defined by a first portion of the surface and a second portion of the surface, the first portion of the surface extending along the impeller and the second portion of the surface extending past the rim of the impeller.

Example 9 includes any preceding clause(s) of Example 8, wherein the housing includes a shroud and a backplate coupled to the shroud and the housing inlet is in the shroud.

Example 10 includes any preceding clause(s) of any one or more of Examples 8 and 9, wherein the second portion of the surface and a portion of the blower form a flow path in the housing to the blower inlet.

Example 11 includes any preceding clause(s) of any one or more of Examples 8-10, further including a heat sink, the flow path to receive air moving in a direction extending from the heat sink toward the blower.

Example 12 includes any preceding clause(s) of any one or more of Examples 8-11, wherein the first portion of the surface defines a first portion of an edge of the housing inlet and the second portion of the surface defines a second portion of the edge of the housing inlet, the first portion of the edge having a first shape and the second portion of the edge having a second shape different than the first shape.

Example 13 includes any preceding clause(s) of any one or more of Examples 8-12, where the first portion of the edge is curved.

Example 14 includes any preceding clause(s) of any one or more of Examples 8-13, wherein the housing inlet has a non-circular shape.

Example 15 includes a graphics card including a blower having a blower inlet and a shaft; and a shroud including an opening to the blower inlet, a surface of the shroud defining an edge of the opening, a first portion of the edge closer to the shaft than a second portion of the edge is to the shaft.

Example 16 includes any preceding clause(s) of Example 15, wherein the blower includes vanes and a portion of the surface including the first portion of the edge covers a first set of the vanes.

Example 17 includes any preceding clause(s) of any one or more of Examples 15 and 16, wherein an airflow path is defined by a portion of the blower and the portion of the surface including the first portion of the edge.

Example 18 includes any preceding clause(s) of any one or more of Examples 15-17, further including a heat sink, wherein the portion of the blower is adjacent to the heat sink.

Example 19 includes any preceding clause(s) of any one or more of Examples 15-18, wherein the heat sink includes a ramped portion and the portion of the blower is adjacent to the ramped portion of the heat sink.

Example 20 includes any preceding clause(s) of any one or more of Examples 15-19, further including a vent in the shroud.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus comprising:
a housing;
a blower in the housing, the blower having a blower inlet; and
an inlet defined by a surface of the housing, the inlet having a first inlet portion defined by a first portion of the surface and a second inlet portion defined by a second portion of the surface, the second portion of the surface extending over a portion of the blower inlet.

2. The apparatus of claim 1, wherein the first inlet portion defines a first shape and the second inlet portion defines a second shape different than the first shape.

3. The apparatus of claim 2, wherein the first inlet portion has a semi-circular shape.

4. The apparatus of claim 2, wherein the second inlet portion is straight.

5. The apparatus of claim 1, wherein the blower includes an impeller and the first portion of the surface extends along a rim of the impeller and the second portion of the surface extends past the rim of the impeller.

6. The apparatus of claim 5, wherein a flow path in the housing is defined between the second portion of the surface and the rim of the impeller, the flow path extending to an edge of the inlet defined by the first inlet portion.

7. The apparatus of claim 1, wherein the surface is a first surface of the housing and further includes a vent defined in a second surface of the housing.

8. An apparatus comprising:
a blower having a blower inlet and an impeller, the impeller having a rim; and
a housing carrying the blower, the housing having a housing inlet defined in a surface of the housing, the housing inlet opening to the blower inlet, the housing inlet defined by a first portion of the surface and a second portion of the surface, the first portion of the surface extending along the impeller and the second portion of the surface extending past the rim of the impeller.

9. The apparatus of claim 8, wherein the housing includes a shroud and a backplate coupled to the shroud and the housing inlet is in the shroud.

10. The apparatus of claim 8, wherein the second portion of the surface and a portion of the blower form a flow path in the housing to the blower inlet.

11. The apparatus of claim 10, further including a heat sink, the flow path to receive air moving in a direction extending from the heat sink toward the blower.

12. The apparatus of claim 8, wherein the first portion of the surface defines a first portion of an edge of the housing inlet and the second portion of the surface defines a second portion of the edge of the housing inlet, the first portion of the edge having a first shape and the second portion of the edge having a second shape different than the first shape.

13. The apparatus of claim 12, where the first portion of the edge is curved.

14. The apparatus of claim 8, wherein the housing inlet has a non-circular shape.

15. A graphics card comprising:
a blower having a blower inlet and a shaft; and
a shroud including an opening to the blower inlet, a surface of the shroud defining an edge of the opening, a first portion of the edge closer to the shaft than a second portion of the edge is to the shaft.

16. The graphics card of claim 15, wherein the blower includes vanes and a portion of the surface including the first portion of the edge covers a first set of the vanes.

17. The graphics card of claim 15, wherein an airflow path is defined by a portion of the blower and the portion of the surface including the first portion of the edge.

18. The graphics card of claim 17, further including a heat sink, wherein the portion of the blower is adjacent to the heat sink.

19. The graphics card of claim 18, wherein the heat sink includes a ramped portion and the portion of the blower is adjacent to the ramped portion of the heat sink.

20. The graphics card of claim 15, further including a vent in the shroud.
